(19) United States
(12) Patent Application Publication
(10) Pub. No.: US 2026/0304875 A1
(43) Pub. Date: Oct. 1, 2026

(54) GROUP III NITRIDE SEMICONDUCTOR EPITAXIAL WAFER AND ELECTRONIC DEVICE

(71) Applicant: Panasonic Holdings Corporation, Osaka (JP)

(72) Inventors: Tomoaki SUMI, Osaka (JP); Takashi KANO, Shiga (JP)

(21) Appl. No.: 19/564,928

(22) Filed: Mar. 12, 2026

(30) Foreign Application Priority Data
Mar. 25, 2025 (JP) 2025-049881

(51) Int. Cl. H10D 62/824; H10D 62/60; H10P 14/20; H10P 14/24; H10P 90/00

(52) U.S. Cl. CPC H10D 62/824; H10D 62/60; H10P 14/24; H10P 14/2908; H10P 14/3416; H10P 90/1904

(57) ABSTRACT

A Group III nitride semiconductor epitaxial wafer includes: a Group III nitride semiconductor substrate exhibiting n-type conductivity and having a carrier concentration of 10²⁰ cm⁻³ or more; a first Group III nitride semiconductor film epitaxially grown on the Group III nitride semiconductor substrate, the first Group III nitride semiconductor film containing Al and Ga as Group III elements; and a second Group III nitride semiconductor film epitaxially grown on the first Group III nitride semiconductor film.

### CROSS REFERENCE TO RELATED APPLICATION

This application claims a priority of Japanese Patent Application No. 2025-49881 filed on Mar. 25, 2025, the contents of which are incorporated herein by reference.

### BACKGROUND OF THE INVENTION

### 1. Field of the Invention

The present disclosure relates to a Group III nitride semiconductor epitaxial wafer having a Group III nitride semiconductor substrate, a first Group III nitride semiconductor film epitaxially grown thereon, and a second Group III nitride semiconductor film epitaxially grown on the first Group III nitride semiconductor film, and to an electronic device using the Group III nitride semiconductor epitaxial wafer.

### 2. Description of the Related Art

Group III nitride semiconductors are used in fields such as optical devices such as semiconductor lasers and light-emitting diodes, as well as high-frequency or high-power electronic devices. These semiconductors have attracted particular attention in recent years because they are expected to reduce switching losses at the time of power conversion compared to silicon-based devices. In order to fabricate high-frequency or high-power electronic devices, it is necessary to fabricate the devices on high-quality Group III nitride semiconductor substrates that can suppress the occurrence of crystal defects in the device layer.

Methods for producing Group III nitride crystals include, for example, hydride vapor phase epitaxy (hereinafter also referred to as HVPE method), ammonothermal, sodium flux, and oxide vapor phase epitaxy (hereinafter also referred to as OVPE method).

In the HVPE method, which is most often used as a substrate production method, hydrogen halide gas is introduced onto a single Group III source material to generate a halide gas, and the generated Group III element halide gas is used as a source gas for crystal growth. For example, when growing gallium nitride crystals, HCl gas is introduced into Ga metal to produce gallium chloride (e.g., GaCl₂) gas, and the gallium chloride-containing gas is used as a Group III source, thereby achieving high-speed growth at 1 mm/h or more. In the HVPE method, it is known that Group III nitride crystals with N-type conductivity can be obtained mainly by adding silicon element to the Group III nitride crystals.

In the OVPE method, an oxide source gas is used to add a high concentration of oxygen element to a Group III nitride crystal to produce the crystal (see, e.g., WO2015/053341A1). In this method, a Group III oxide gas reacts with a nitrogen element-containing gas to produce a Group III nitride crystal. The substrate obtained by this method has a low dislocation density of the order of 10⁴ cm⁻², and the OVPE method is one means for obtaining a high-quality Group III nitride crystal.

The present inventors have found, however, that although a Group III nitride semiconductor substrate obtained by OVPE has a high carrier concentration of 10²⁰cm⁻³or more, a Group III nitride semiconductor film epitaxially grown directly thereon has the problem of not being able to obtain sufficient flatness, as shown in FIGS. 7A to 7C FIG 7A shows an Atomic Force Microscope (AFM) image of a 1 μm×1 μm surface, FIG. 7B shows an AFM image of a 10 μm×10 μm surface, and FIG. 7C shows an AFM image of a 90 μm×90 μm surface. The root mean square height (Rq: JIS B0601: ISO 4287:1997) of each sample was 0.377 nm (1 μm square) in FIGS. 7A, 0.793 nm (10 μm square) in FIGS. 7B, and 9.66 nm (30 μm square) in FIG. 7C This indicates that the values are low in narrow areas but high in wide areas, and that ridge structures are generated on the surface, preventing sufficient flatness.

### SUMMARY

The present disclosure is intended to solve the above-mentioned problems, and one non-limiting and exemplary embodiments provides a Group III nitride semiconductor epitaxial wafer having a flat outermost surface, which includes a Group III nitride semiconductor film epitaxially grown on a Group III nitride semiconductor substrate obtained by OVPE.

In one general aspect, the techniques disclosed here feature:
a Group III nitride semiconductor epitaxial wafer includes: a Group III nitride semiconductor substrate exhibiting n-type conductivity and having a carrier concentration of 10²⁰cm⁻³ or more;
a first Group III nitride semiconductor film epitaxially grown on the Group III nitride semiconductor substrate, the first Group III nitride semiconductor film containing Al and Ga as Group III elements; and a
second Group III nitride semiconductor film epitaxially grown on the first Group III nitride semiconductor film.

In another general aspect, the techniques disclosed here feature: an electronic device using the Group III nitride semiconductor epitaxial wafer of the above aspect.

In another general aspect, the techniques disclosed here feature:
a method for producing a Group III nitride semiconductor epitaxial wafer, comprising:
   forming a Group III nitride semiconductor substrate exhibiting n-type conductivity and having a carrier concentration of 10²⁰cm⁻³ or more by OVPE method;
   epitaxially growing a first Group III nitride semiconductor film containing Al and Ga as Group III elements on the Group III nitride semiconductor substrate; and
   epitaxially growing a second Group III nitride semiconductor film on the first Group III nitride semiconductor film.

A Group III nitride semiconductor epitaxial wafer according to the present disclosure includes a first Group III nitride semiconductor film containing Al and Ga as Group III elements epitaxially grown on a Group III nitride semiconductor substrate, and a second Group III nitride semiconductor film epitaxially grown on the first Group III nitride semiconductor film. By disposing as an intermediate layer the first Group III nitride semiconductor film containing Al and Ga as Group III elements, it is possible to ensure the flatness of the second Group III nitride semiconductor film at the uppermost surface.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a schematic cross-sectional view showing the cross-sectional structure of a group III nitride semiconductor epitaxial wafer according to a first embodiment;

FIGS. 2A and 2b are flowcharts of a method for producing a Group III nitride semiconductor substrate constituting the Group III nitride semiconductor epitaxial wafer according to the first embodiment;

FIG. 3 is a schematic cross-sectional view showing the cross-sectional structure of a production apparatus for the Group III nitride semiconductor substrate constituting the Group III nitride semiconductor epitaxial wafer according to the first embodiment;

FIG. 4A is Table 1 showing the production conditions of a group III nitride semiconductor epitaxial wafer according to Example 1;

FIG. 4B is Table 2 showing the production conditions of a group III nitride semiconductor epitaxial wafer according to Example 2;

FIG. 4C is Table 3 showing the production conditions of a group III nitride semiconductor epitaxial wafer according to Example 3;

FIG. 5 is Table 4 showing the composition of each layer of the Group III nitride semiconductor epitaxial wafers according to Examples 1 to 3;

FIG. 6 is Table 5 showing AFM images of the surfaces of the group III nitride semiconductor epitaxial wafers according to Examples 1 to 3 and the root mean square (RMS) roughness values of the surfaces within a 30 μm square area;

FIG. 7A shows an AFM image of a 1 μm×1 μm area of the surface of a Group III nitride semiconductor film epitaxially grown directly on a Group III nitride semiconductor substrate obtained by OVPE;

FIG. 7B shows an AFM image of a 10 μm×10 μm area of the surface of the Group III nitride semiconductor film epitaxially grown directly on the Group III nitride semiconductor substrate obtained by OVPE;

FIG. 7C shows an AFM image of a 90 μm×90 μm area of the surface of the Group III nitride semiconductor film epitaxially grown directly on the Group III nitride semiconductor substrate obtained by OVPE;

FIG. 8 is Table 6 showing the composition of each layer of the Group III nitride semiconductor epitaxial wafers according to Example 3 and Experimental Examples 4 to 7, and the Al composition ratio in the first Group III nitride semiconductor film; and

FIG. 9 is Table 7 showing AFM images of the surfaces of the Group III nitride semiconductor epitaxial wafers according to Example 3 and Experimental Examples 4 to 7, and the root mean square (RMS) roughness values of the surfaces within a 30 μm square.

### DETAILED DESCRIPTION

A Group III nitride semiconductor epitaxial wafer according to a first aspect, includes:
a Group III nitride semiconductor substrate exhibiting n-type conductivity and having a carrier concentration of 10²⁰cm⁻³ or more;
a first Group III nitride semiconductor film epitaxially grown on the Group III nitride semiconductor substrate, the first Group III nitride semiconductor film containing Al and Ga as Group III elements; and
a second Group III nitride semiconductor film epitaxially grown on the first Group III nitride semiconductor film.

In the Group III nitride semiconductor epitaxial wafer according to a second aspect in addition to the first aspect, the second Group III nitride semiconductor film at the uppermost surface may have a root mean square (RMS) roughness value of 1 nm or less over a 30 μm square area of the surface.

In the Group III nitride semiconductor epitaxial wafer according to a third aspect in addition to the first or second aspect, the Group III nitride semiconductor substrate may be a gallium nitride substrate.

In the Group III nitride semiconductor epitaxial wafer according to a fourth aspect in addition to any one of first to third aspects, the second Group III nitride semiconductor film formed above the first Group III nitride semiconductor film may include a Group III nitride semiconductor film having an Al composition ratio lower than the Al composition ratio of the first Group III nitride semiconductor film.

In the Group III nitride semiconductor epitaxial wafer according to a fifth aspect in addition to any one of first to fourth aspects, the second Group III nitride semiconductor film formed above the first Group III nitride semiconductor film may include a Group III nitride semiconductor film having a carrier concentration of 10¹⁷ cm⁻³ or less.

In the Group III nitride semiconductor epitaxial wafer according to a sixth aspect in addition to any one of first to fifth aspects, the dopant element of the Group III nitride semiconductor substrate may be oxygen.

In the Group III nitride semiconductor epitaxial wafer according to a seventh aspect in addition to any one of first to sixth aspects, the Al composition ratio relative to the total amount of the Group III elements in the first Group III nitride semiconductor film may be 0.001 or more and 0.3 or less, where the total amount of the Group III elements in the first Group III nitride semiconductor film is 1.

In the Group III nitride semiconductor epitaxial wafer according to an eighth aspect in addition to any one of first to seventh aspects, the thickness of the first Group III nitride semiconductor film may be 0.02 μm or more and 1 μm or less.

An electronic device according to a ninth aspect, using the Group III nitride semiconductor epitaxial wafer of any one of first to eighth aspects.

A method for producing a Group III nitride semiconductor epitaxial wafer according to a tenth aspect, includes:
forming a Group III nitride semiconductor substrate exhibiting n-type conductivity and having a carrier concentration of 10²⁰cm⁻³ or more by OVPE method;
epitaxially growing a first Group III nitride semiconductor film containing Al and Ga as Group III elements on the Group III nitride semiconductor substrate; and
epitaxially growing a second Group III nitride semiconductor film on the first Group III nitride semiconductor film.

A group III nitride semiconductor epitaxial wafer and a production method thereof according to embodiments of the present disclosure will now be described with reference to the accompanying drawings.

### First Embodiment

### Group III Nitride Semiconductor Epitaxial Wafer

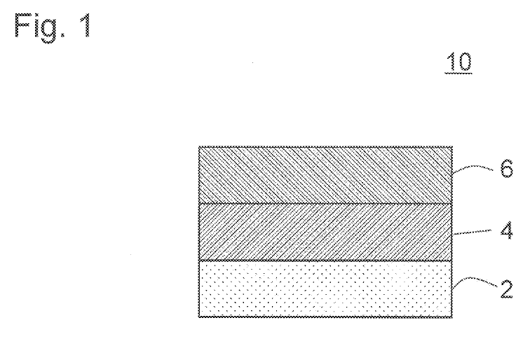

FIG. 1 is a schematic cross-sectional view showing an example of a nitride semiconductor epitaxial wafer 10 according to the first embodiment.

The Group III nitride semiconductor epitaxial wafer 10 according to the present disclosure comprises at least three layers: a Group III nitride semiconductor substrate 2, a first Group III nitride semiconductor film 4 including an epitaxial layer epitaxially grown thereon, and a second Group III nitride semiconductor film 6 epitaxially grown on the first Group III nitride semiconductor film 4. The Group III nitride semiconductor substrate 2 exhibits n-type conductivity and has a carrier concentration of 10²⁰cm⁻³or higher.

The components constituting this Group III nitride semiconductor epitaxial wafer 10 will be described below.

### Group III Nitride Semiconductor Substrate

The group III nitride semiconductor substrate 2 is doped with impurities that act as n-type dopants to reduce the on-resistance during operation, and exhibits n-type conductivity, with a carrier concentration of 10²⁰cm⁻³ or more.

The n-type dopant element of the group III nitride semiconductor substrate 2 may include, for example, at least one element selected from the group consisting of silicon element, germanium element, and oxygen element.

The n-type dopant element of the Group III nitride semiconductor substrate more preferably includes, for example, oxygen element, which makes it possible to easily add oxygen element to the Group III nitride semiconductor substrate, particularly when the Group III nitride semiconductor substrate to be used as the substrate is fabricated by OVPE.

When oxygen is the main n-type dopant element in a Group III nitride semiconductor substrate, the oxygen is preferably added at a composition level of, for example, 10²⁰ atoms∙ cm⁻³ or more, which makes it easy to achieve a carrier concentration of 10²⁰ cm⁻³ or more in the Group III nitride semiconductor substrate.

The group III nitride semiconductor substrate may be GaN obtained by OVPE.

### First Group III Nitride Semiconductor Film

The first Group III nitride semiconductor film 4 is a Group III nitride semiconductor film containing Al and Ga as Group III elements, epitaxially grown on the Group III nitride semiconductor substrate 2. When the total amount of Group III elements in the first Group III nitride semiconductor film is taken as 1, the Al composition ratio relative to the total amount of Group III elements may be, for example, not less than 0.001 and not more than 0.3.

The epitaxial layer constituting the first Group III nitride semiconductor film may be a single layer, or may have a structure including two or more layers.

The first Group III nitride semiconductor film may have a thickness of, for example, 0.02 μm or more and 1 μm or less.

The thickness of the first Group III nitride semiconductor film may be 0.02 μm or more. If the Group III nitride semiconductor film is thinner than 0.02 μm, a sufficiently stable surface is not formed when forming an epitaxial layer on the substrate, and sufficient flatness cannot be obtained.

The thickness of the first Group III nitride semiconductor film may be 1 μm or less. If the thickness exceeds 1 μm, the influence of lattice mismatch with the second Group III nitride semiconductor film epitaxially grown thereon may occur.

### Second Group III Nitride Semiconductor Film

The second Group III nitride semiconductor film is a Group III nitride semiconductor film epitaxially grown on a Group III nitride semiconductor substrate. The second Group III nitride semiconductor film may have a thickness of, for example, 1 μm or more and 30 μm or less. By making the second Group III nitride semiconductor film 1 μm or more, a sufficiently stable surface is formed when forming an epitaxial layer on the substrate, allowing a device to be formed on the uppermost surface. Furthermore, if the thickness is 30 μm or less, it is easy to maintain the flatness of the epitaxial layer.

The thickness of the second Group III nitride semiconductor film is more preferably 1 μm or more and 8 μm or less. By making it 1 μm or more and 8 μm or less, a film having a sufficiently stable surface can be formed and sufficient flatness can be maintained even when the lattice mismatch between the substrate and the epitaxial layer is large.

The epitaxial layer constituting the second Group III nitride semiconductor film may be a single layer, or may have a structure of two or more layers.

The second Group III nitride semiconductor film has a sufficient flatness, for example, a root mean square (RMS) roughness of 1 nm or less when measured over a 30 μm square area.

Furthermore, the second Group III nitride semiconductor film may have a lower Al composition ratio relative to all Group III elements than the first Group III nitride semiconductor film. When the second Group III nitride semiconductor film is made up of two or more epitaxial layers, the Al composition ratio may decrease from the film closest to the first Group III nitride semiconductor film toward the upper layers.

Furthermore, when used in electronic devices, it is possible to implement devices with low resistance during operation and low leakage current.

### Electronic Devices

The above Group III nitride semiconductor epitaxial wafer may be used in electronic devices, thereby implementing devices with flat surfaces, low resistance during operation, and low leakage current.

### Method for Producing Group III Nitride Semiconductor Epitaxial Wafer

The method for producing a group III nitride semiconductor epitaxial wafer according to the first embodiment includes the following steps.
(1) A Group III nitride semiconductor substrate exhibiting n-type conductivity and having a carrier concentration of 10²⁰cm⁻³or more is formed by OVPE. The method for producing a Group III nitride semiconductor substrate by OVPE will be described later.
(2) A first Group III nitride semiconductor film containing Al and Ga as Group III elements is epitaxially grown on a Group III nitride semiconductor substrate. The first Group III nitride semiconductor film is, for example, AlGaN. More specifically, when the chemical formula of the first Group III nitride semiconductor film is written as (AlₓGa₁₋ₓ)N, the Al composition ratio x is, for example, 0.001 or more and 0.3 or less. By setting the Al composition ratio x within the above range, sufficient flatness can be obtained for the first Group III nitride semiconductor film, and the occurrence of lattice distortion between the first Group III nitride semiconductor film and the underlying Group III nitride semiconductor substrate can be suppressed.
(3) A second Group III nitride semiconductor film is epitaxially grown on the first Group III nitride semiconductor film. Since the first Group III nitride semiconductor film has sufficient flatness, the second Group III nitride semiconductor film can have a sufficient flatness, for example, a root mean square (RMS) roughness value of 1 nm or less over a 30 μm square of the surface. As a result, the second Group III nitride semiconductor film having a sufficient flatness as a flat outermost surface.

In this manner, the group III nitride semiconductor epitaxial wafer according to the first embodiment can be obtained.

### Outline of Method for Producing Group III Nitride Semiconductor Substrate

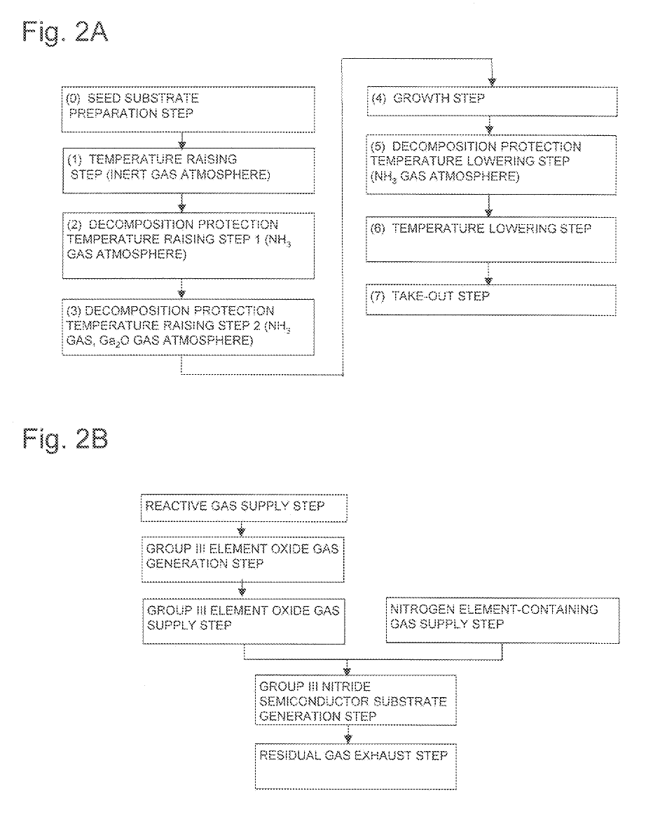

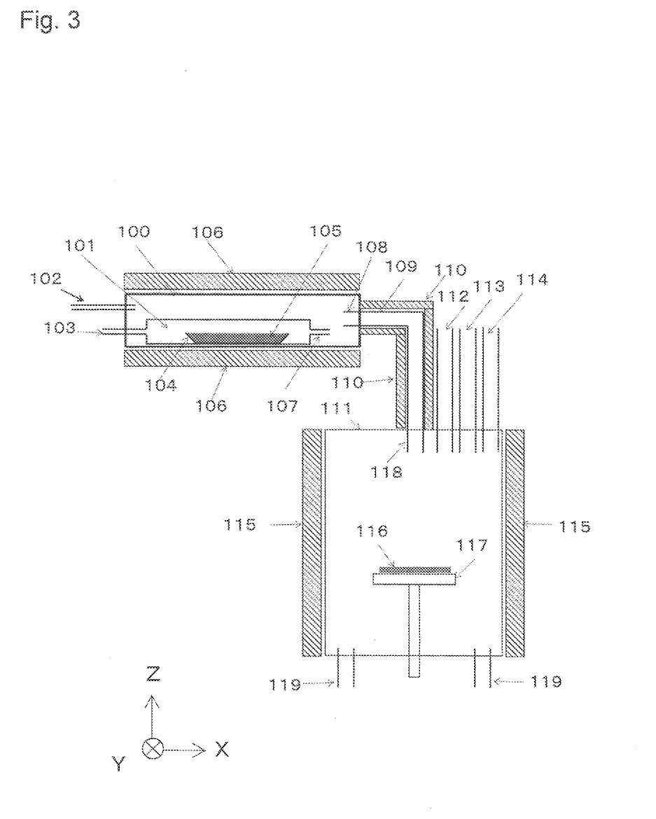

The outline of a method for producing a Group III nitride semiconductor substrate constituting a Group III nitride semiconductor epitaxial wafer according to the first embodiment based on the OVPE method will be described with reference to the flowchart of FIGS. 2A, 2B and 3. FIG. 2A is a chronological flowchart of the production method. FIG. 2B shows, as steps, functional units from upstream to downstream in a production apparatus used in this production method.

In a seed substrate preparation step of preparing a seed substrate 116, the seed substrate 116 is placed on a substrate susceptor 117.

In a temperature-raise step, the temperature of a growth chamber 111 is raised to 100°C (Celsius Degree) or higher and lower than 500°C in an inert gas atmosphere.

In a decomposition protection temperature-raise step 1, the temperature of the growth chamber 111 is raised to 500°C or higher and lower than 1100°C in an NH₃ gas atmosphere.

In a decomposition protection temperature-raise step 2, the temperature of the growth chamber 111 is raised to 1100°C or higher and lower than 1500°C in an atmosphere of NH₃gas and Ga₂O gas.

In a growth step of growing a Group III nitride semiconductor substrate on the seed substrate 116, a Group III element oxide gas is generated in a source chamber 100 and supplied to the growth chamber 111, and a nitrogen element-containing gas is also supplied to the growth chamber 111, thereby growing the Group III nitride semiconductor substrate on the seed substrate 116.

The growth step further includes a reactive gas supply step, a Group III element oxide gas generation step, a Group III element oxide gas supply step, a nitrogen element-containing gas supply step, a Group III nitride semiconductor substrate generation step, and a residual gas exhaust step. Note that the steps included in the growth step may be performed simultaneously within the Group III nitride semiconductor substrate production apparatus.

In the reactive gas supply step, a reactive gas is supplied to the source reaction chamber.

In the Group III element oxide gas generation step, the starting Group III element source is reacted with a reactive gas (a reducing gas if the starting Group III element source is an oxide, and an oxidizing gas if the starting Group III element source is a metal) to generate a Group III element oxide gas.

In the Group III element oxide gas supplying step, the Group III element oxide gas produced in the Group III element oxide gas producing step is supplied to the growth chamber.

In the nitrogen element-containing gas supplying step, a nitrogen element-containing gas is supplied to the growth chamber.

In the Group III nitride semiconductor substrate generation step, the Group III element oxide gas supplied into the growth chamber in the Group III element oxide gas supplying step and the nitrogen element-containing gas supplied into the growth chamber in the nitrogen element-containing gas supplying step are reacted with each other to grow a Group III nitride semiconductor substrate on the seed substrate.

In the residual gas exhaust step, unreacted gases that do not contribute to the production of a Group III nitride semiconductor substrate are exhausted to the outside of the chamber.

In a decomposition protection temperature-lowering step, the temperatures of the source chamber 100 and the growth chamber 111 are lowered to 500°C while supplying NH₃ gas in order to suppress decomposition of the Group III nitride semiconductor substrate grown on the seed substrate 116.

In a temperature-lowering step, the temperatures of the source chamber 100 and the growth chamber 111 are lowered to below 100°C in an inert gas atmosphere.

In a take-out step, the seed substrate 116 having the group III nitride substrate grown thereon is took out from the growth chamber 111.

### Outline of Group III Nitride Semiconductor Substrate Production Apparatus

The outline of a production apparatus used in a method for producing a Group III nitride semiconductor substrate constituting the Group III nitride semiconductor epitaxial wafer according to the first embodiment will be described with reference to FIG. 3. FIG. 3 is a schematic cross-sectional view of the production apparatus for a Group III nitride semiconductor substrate constituting the Group III nitride semiconductor epitaxial wafer according to the first embodiment.

In FIG. 3, the size, ratio, etc. of each component may differ from the actual product. The apparatus for producing a Group III nitride semiconductor substrate has a source reaction chamber 101 disposed within the source chamber 100, and a source boat 104 carrying a starting Group III element source 105 disposed within the source reaction chamber 101. A reactive gas supply pipe 103 is connected to the source reaction chamber 101, supplying a gas that reacts with the starting Group III element source 105. The source reaction chamber 101 has a Group III element oxide gas discharge port 107 for discharging the generated Group III element oxide gas. When the starting Group III source is an oxide, a reducing gas is used as the reactive gas. When the starting Group III source is a metal, an oxidizing gas is used as the reactive gas. A first carrier gas supply port 102 for supplying a first carrier gas is connected to the source chamber 100, and the first carrier gas supplied from the first carrier gas supply port 102 and the Group III element oxide gas discharged from the Group III element oxide gas discharge port 107 flow from a gas discharge port 108 through a connecting pipe 109 to the growth chamber 111, and are supplied into the growth chamber 111 from a gas supply port 118 connected to the growth chamber 111. The growth chamber 111 has the gas supply port 118, a third carrier gas supply port 112, a nitrogen element-containing gas supply port 113, a second carrier gas supply port 114, and an exhaust port 119. The growth chamber 111 includes the substrate susceptor 117 on which the seed substrate 116 is placed.

### Details of Production Method and Production Apparatus

The method for producing a group III nitride semiconductor substrate according to the first embodiment will be described in detail with reference to FIGS. 2A, 2B and 3.

In the first embodiment, metal Ga is used as the starting group III element source 105, but the present invention is not limited thereto, and for example, Al or In may also be used.

First, the seed substrate 116 is prepared. For example, gallium nitride, gallium arsenide, silicon, sapphire, silicon carbide, zinc oxide, gallium oxide, or ScAlMgO₄ can be used as the seed substrate 116. In the first embodiment, gallium nitride is used as the seed substrate 116.

Description will be given based on FIG. 2A.

In the temperature-raise step, the temperature of the growth chamber is raised in an inert gas atmosphere to a temperature that does not cause decomposition of the seed substrate 116. In the production of a Group III nitride semiconductor substrate by the OVPE method, heating is performed in an inert gas (e.g., N₂ gas) atmosphere to approx. 500°C.

In the decomposition protection temperature-raise step 1, the temperature is raised in a nitrogen element-containing gas atmosphere while suppressing decomposition of the seed substrate 116. In the production of a Group III nitride semiconductor substrate by the OVPE method, heating is performed in a state in which an inert gas and a nitrogen element-containing gas, NH₃ gas, are mixed up to a temperature of 500°C or higher but lower than 1100°C. The reason for mixing NH₃is to prevent decomposition of the seed substrate 116 due to desorption of N atoms. Heating may also be performed in a state where H₂ gas is further mixed up.

In the decomposition protection temperature-raise step 2, the temperature is raised in an atmosphere of a Group III oxide gas and a nitrogen element-containing gas while suppressing decomposition of the seed substrate 116. In the production of a Group III nitride semiconductor substrate by the OVPE method, heating is performed up to a temperature of 1100°C. or higher but lower than 1500°C in a state where H₂ gas, an inert gas, a Group III element oxide gas, and a nitrogen element-containing gas NH₃ gas are mixed. The reason for mixing the Group III element oxide gas is that decomposition cannot be suppressed with a nitrogen element-containing gas alone. By applying a driving force for the growth of the Group III nitride semiconductor substrate, it becomes possible to suppress decomposition.

In the growth step, a Group III element oxide gas is generated in the source chamber 100 and supplied to the growth chamber 111, and a nitrogen element-containing gas is also supplied to the growth chamber 111 to grow a Group III nitride semiconductor substrate on the seed substrate 116. Specifically, the growth step includes a reactive gas supply step, a Group III element oxide gas generation step, a Group III element oxide gas supply step, a nitrogen element-containing gas supply step, a Group III nitride semiconductor substrate generation step, and a residual gas exhaust step.

Description will next be given based on FIG. 2B.

In the reactive gas supply step, a reactive gas is supplied from the reactive gas supply pipe 103 to the source reaction chamber 101 in the source chamber 100. As described above, a reducing gas or an oxidizing gas can be used as the reactive gas as necessary. In the first embodiment, since metal Ga is used as the group III element source 105, H₂O gas is used as the reactive gas.

In the Group III element oxide gas generation step, the reactive gas supplied to the source reaction chamber 101 in the reactive gas supply step reacts with Ga, which is the starting Group III element source 105, to generate Ga₂O gas, which is a Group III element oxide gas. The generated Ga₂O gas is discharged from the source reaction chamber 101 to the source chamber 100 via the Group III element oxide gas discharge port 107. The discharged Ga₂O gas is mixed with a first carrier gas supplied to the source chamber from the first carrier gas supply port 102, and supplied to the gas discharge port 108. In the first embodiment, the source chamber 100 is heated by a first heater 106. When the source chamber 100 is heated, the temperature of the source chamber 100 is preferably 800°C. or higher in view of the boiling point of Ga₂O gas. Furthermore, the temperature of the source chamber 100 is preferably set lower than that of the growth chamber 111. When the growth chamber is heated by a second heater 115 as described below, the temperature of the source chamber 100 is preferably set to, for example, less than 1800°C. The starting Group III element source 105 is placed in a source boat 104 disposed in the source reaction chamber 101. The source boat 104 preferably has a shape that can increase the contact area between the reactive gas and the starting Group III element source. For example, the source boat 104 preferably has a multi-tiered dish shape to prevent the starting Group III element source 105 and the reactive gas from passing through the source reaction chamber 101 without contacting each other.

Methods for generating a Group III element oxide gas can be broadly divided into methods for reducing the starting Group III element source 105 and methods for oxidizing the starting Group III element source 105. For example, the reduction method uses an oxide (e.g., Ga₂O₃) as the starting Group III element source 105 and a reducing gas (e.g., H₂ gas, CO gas, CH₄ gas, C₂H₆ gas, H₂S gas, or SO₂ gas) as the reactive gas. On the other hand, the oxidation method uses a non-oxide (e.g.,liquid Ga) as the starting Group III element source 105 and an oxidizing gas (e.g., H₂O gas, O₂ gas, CO gas, CO₂ gas, NO gas, N₂O gas, or NO₂ gas) as the reactive gas. In addition to the starting Group III element source 105, an In source or an Al source can also be employed as the starting Group III element. An inert gas, H₂ gas, or the like can be used as the first carrier gas.

In the Group III element oxide gas supply step, Ga₂O gas generated in the Group III element oxide gas generation step is supplied to the growth chamber 111 via the gas discharge port 108, the connecting pipe 109, and the gas supply port 118. When the temperature of the connecting pipe 109 connecting the source chamber 100 and the growth chamber 111 drops below the temperature of the source chamber 100, a reverse reaction of the reaction for generating the Group III element oxide gas occurs, and the starting Ga source 105 precipitates inside the connecting pipe 109. Therefore, it is preferable that the connecting pipe 109 be heated by a third heater 110 to a temperature higher than that of the first heater 106 so that the temperature does not drop below that of the source chamber 100.

In the nitrogen element-containing gas supplying step, a nitrogen element-containing gas is supplied to the growth chamber 111 from the nitrogen element-containing gas supply port 113. Examples of the nitrogen element-containing gas may include NH₃ gas, NO gas, NO₂ gas, N₂O gas, N₂H₂ gas, and N₂H₄ gas.

In the Group III nitride semiconductor substrate production process, the source gases supplied into the growth chamber through each supply process are reacted to grow a Group III nitride semiconductor substrate on the seed substrate 116. The growth chamber 111 is preferably heated by the second heater 115 to a temperature at which the Group III element oxide gas and the nitrogen element-containing gas react. At this time, the temperature of the growth chamber 111 is preferably controlled so as not to fall below the temperature of the source chamber 100, in order to prevent a reverse reaction of the reaction that produces the Group III element oxide gas. The temperature of the growth chamber 111 heated by the second heater 115 is preferably 1000°C. or higher and 1800°C. or lower. Furthermore, in order to suppress temperature fluctuations in the growth chamber 111 due to the Ga₂O gas generated in the source chamber 100 and the first carrier gas, it is desirable for the second heater 115 and the third heater 111 to be at the same temperature.

The Group III element oxide gas supplied to the growth chamber 111 via the Group III element oxide supply step and the nitrogen element-containing gas supplied to the growth chamber 111 via the nitrogen element-containing gas supply step are mixed upstream of the seed substrate 116, whereby a Group III nitride semiconductor substrate can be grown on the seed substrate 116.

The reactive gas supplying step, the Group III element oxide gas generating step, the Group III element oxide gas supplying step, the nitrogen element-containing gas supplying step, the Group III nitride semiconductor substrate generating step, and the residual gas exhaust step, which are included in the growth step, may be performed at the same time.

The second carrier gas can be an inert gas, H₂ gas, or the like.

In the residual gas exhaust process, the unreacted Group III element oxide gas and nitrogen element-containing gas, as well as the first carrier gas, second carrier gas, and third carrier gas, are exhausted from the exhaust port 119.

In the decomposition protection temperature-lowering step, the temperature is lowered in a nitrogen element-containing gas atmosphere while suppressing decomposition of the Group III nitride semiconductor substrate. In the production of a Group III nitride semiconductor substrate by the OVPE method, the cooling is performed to 500°C or lower in a state where an inert gas and a nitrogen element-containing gas, NH₃ gas, are mixed.

In the temperature-lowering step, the temperature is lowered in an inert gas atmosphere to a temperature at which the Group III nitride semiconductor substrate can be removed from the growth chamber.

In the first embodiment, the seed substrate 116 having the group III nitride semiconductor substrate grown thereon is removed from growth chamber 111 after the temperature-lowering step.

In this manner, a group III nitride semiconductor substrate can be obtained.

### First Group III Nitride Semiconductor Film

The first Group III nitride semiconductor film is obtained by epitaxially growing a Group III nitride semiconductor film containing Al and Ga as Group III elements on a Group III nitride semiconductor substrate. The step of epitaxially growing the first Group III nitride semiconductor film may be based on OVPE by replacing the seed substrate with a Group III nitride semiconductor substrate and the starting Group III element source with one containing Al and Ga in the above apparatus and method for producing a Group III nitride semiconductor substrate. This allows the first Group III nitride semiconductor film to be epitaxially grown on the Group III nitride semiconductor substrate without removing it from the growth chamber after the Group III nitride semiconductor substrate is produced. Note that the production method for the first Group III nitride semiconductor film is not limited to the above production method based on OVPE.

### Second Group III Nitride Semiconductor Film

The second Group III nitride semiconductor film is obtained by epitaxially growing a Group III nitride semiconductor film on the first Group III nitride semiconductor film. The step of epitaxially growing the second Group III nitride semiconductor film may be performed based on OVPE by replacing the seed substrate with a first Group III nitride semiconductor substrate in the above-described Group III nitride semiconductor substrate production apparatus and production method. This allows the second Group III nitride semiconductor film to be epitaxially grown on the first Group III nitride semiconductor film continuously after the first Group III nitride semiconductor film is produced without removing the substrate from the growth chamber. Note that the production method of the second Group III nitride semiconductor film is not limited to the above production method based on OVPE.

### Example 1

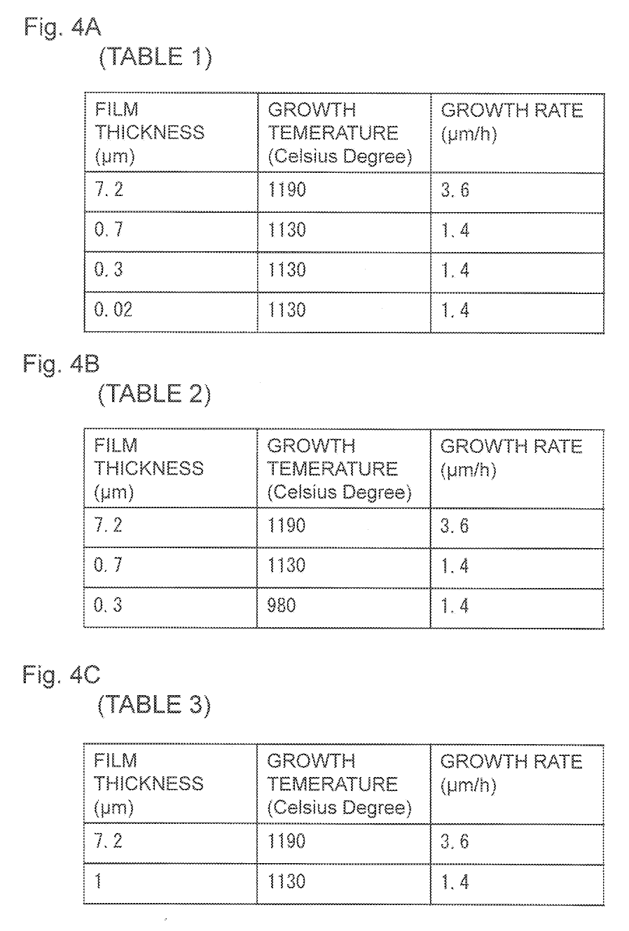

FIG. 4A is Table 1 showing the production conditions for a Group III nitride semiconductor epitaxial wafer according to Example 1. Table 1 shows the production conditions for a Group III nitride semiconductor epitaxial wafer consisting of four layers with film thicknesses of 0.02 μm, 0.3 μm, 0.7 μm, and 7.2 μm stacked on a Group III nitride semiconductor substrate obtained by OVPE.

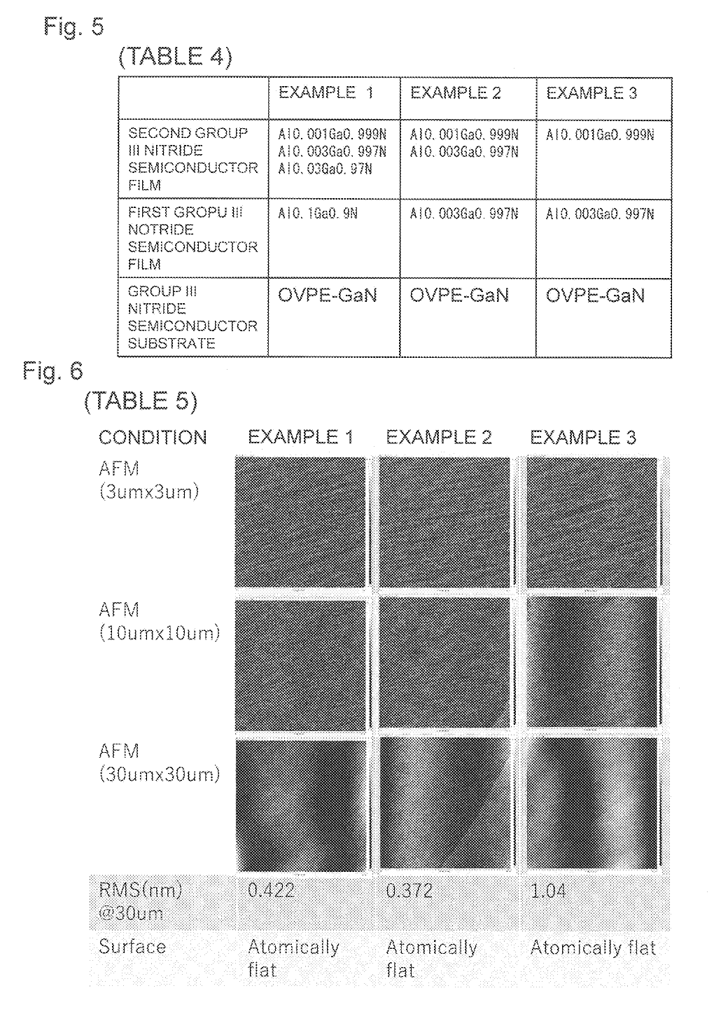

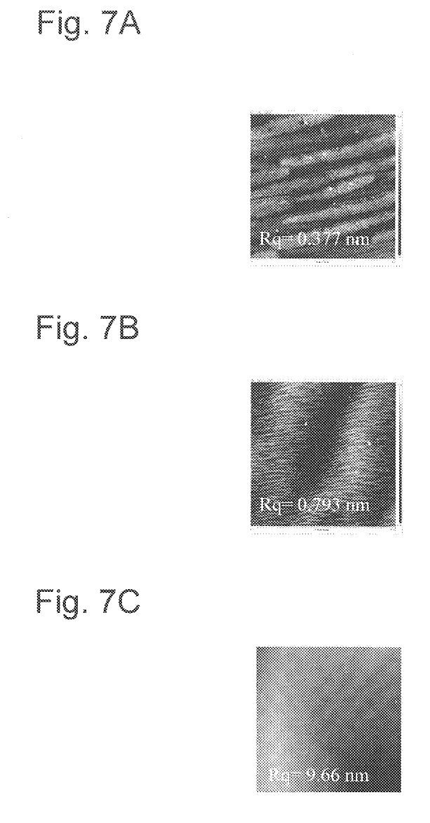

FIG. 5 is Table 4 showing the composition of each layer of the Group III nitride semiconductor epitaxial wafers according to Examples 1 to 3. As shown in the composition of each layer in Example 1 in FIG. 5, the Group III nitride semiconductor substrate is GaN grown by the OVPE method, the lower layer is a first Group III nitride semiconductor film containing Al and Ga as Group III elements, and the upper layer is a second Group III nitride semiconductor film. As shown in FIG. 5, the Al composition ratio relative to the amount of the all Group III elements decreases from the lower layer to the upper layer.

### Example 2

FIG. 4B is Table 2 showing the production conditions for a Group III nitride semiconductor epitaxial wafer according to Example 2. Table 2 shows the production conditions for a Group III nitride semiconductor epitaxial wafer consisting of three layers with film thicknesses of 0.3 μm, 0.7 μm, and 7.2 μm stacked on a Group III nitride semiconductor substrate obtained by OVPE.

As shown in the composition of each layer in Example 2 in FIG. 5, the Group III nitride semiconductor substrate is GaN grown by the OVPE method, with one lower layer being a first Group III nitride semiconductor film containing Al and Ga as Group III elements, and two upper layers being a second Group III nitride semiconductor film.

### Example 3

FIG. 4C is Table 3 showing the production conditions for a Group III nitride semiconductor epitaxial wafer according to Example 3. Table 3 shows the production conditions for a Group III nitride semiconductor epitaxial wafer consisting of two layers with film thicknesses of 1 μm and 7.2 μm stacked on a Group III nitride semiconductor substrate obtained by OVPE.

As shown in the composition of each layer in Example 3 in FIG. 5, the Group III nitride semiconductor substrate is GaN grown by the OVPE method, with one lower layer being a first Group III nitride semiconductor film containing Al and Ga as Group III elements, and one upper layer being a second Group III nitride semiconductor film. In comparison with Example 2, Example 3 differs from Example 2 in that the lower layer of the second Group III nitride semiconductor film, which had a two-layer structure, is changed to a film thickness of 1 µm, and is used as the first Group III nitride semiconductor film. That is, from the initial stage of growth on the substrate, a 1 µm thick layer of AlGaN with an Al composition ratio of 0.3% is formed at 1130°C. to form the first Group III nitride semiconductor film.

FIG. 6 is Table 5 showing AFM images of the surfaces of the group III nitride semiconductor epitaxial wafers according to Examples 1 to 3, and values of the root mean square (RMS) roughness of the surfaces within a 30 μm square.

Atomic steps are observed in the AFM image of FIG. 6, and the root mean square (RMS) roughness values in a 30 µm x 30 µm area are 0.422 nm and 0.372 nm, respectively, which are less than 1 nm and show sufficient flatness in Examples 1 and 2. Example 3 also shows a relatively flat surface with a value of 1.04 nm.

As described above, by disposing as the intermediate layer the first Group III nitride semiconductor film containing Al and Ga as Group III elements, it is possible to ensure the flatness of the second Group III nitride semiconductor film on the uppermost surface.

### Example 3 and Experimental Examples 4-7

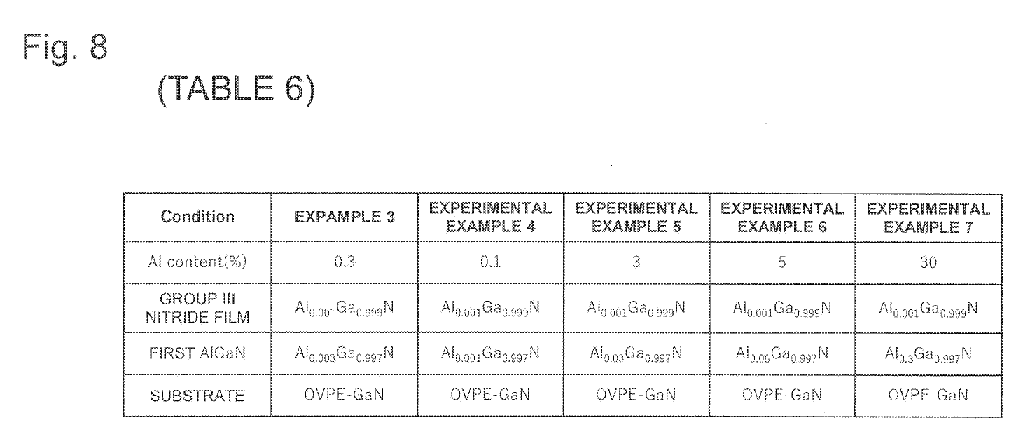

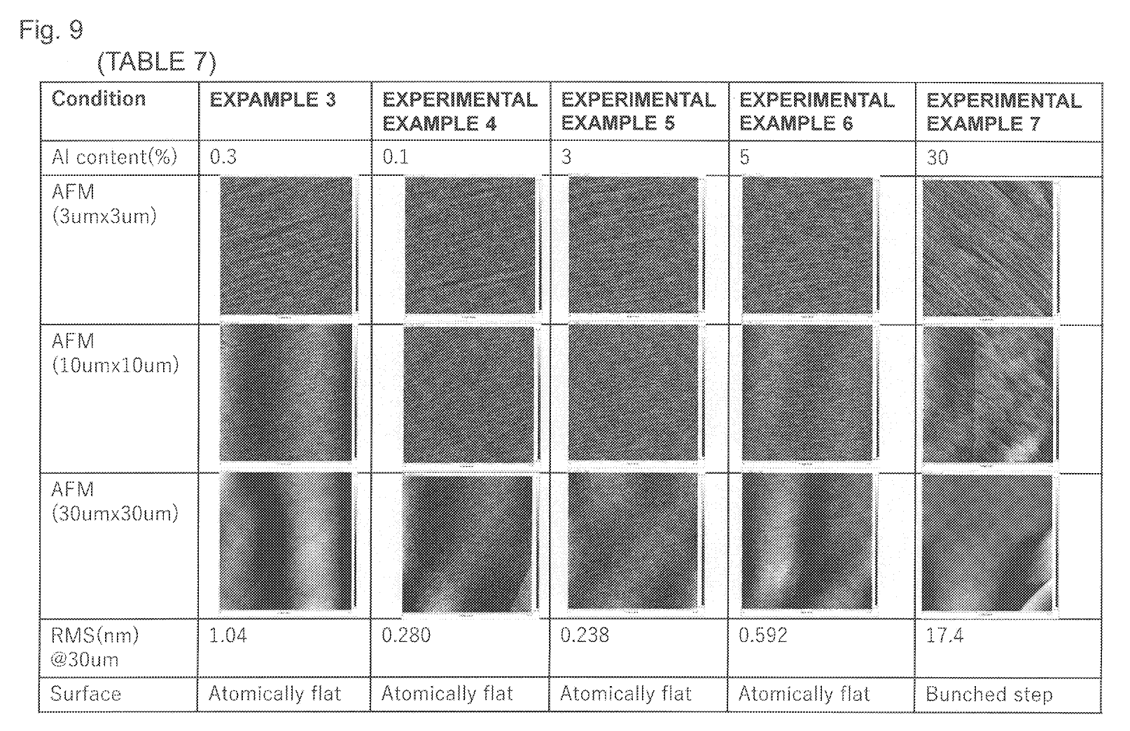

FIG. 8 is Table 6 showing the composition of each layer of the Group III nitride semiconductor epitaxial wafers according to Example 3 and Experimental Examples 4 to 7 and the Al composition ratio in the first Group III nitride semiconductor film. FIG. 9 is Table 7 showing AFM images of the surfaces of the Group III nitride semiconductor epitaxial wafers according to Example 3 and Experimental Examples 4 to 7 and the root mean square (RMS) roughness values of the surfaces over a 30 μm square.

Experimental Examples 4-7 differ from Example 3 in that the Al composition ratio in the first Group III nitride semiconductor film was changed. In Experimental Examples 4-7, as shown in Table 7 of FIG. 8, when the Al composition ratio in the first Group III nitride semiconductor film was 0.1% (Experimental Example 4), 3% (Experimental Example 5), or 5% (Experimental Example 6), atomic steps were observed over a 30-μm square area of the surface, as shown in Table 7 of FIG. 9. Furthermore, the root mean square (RMS) roughness over a 30-μm square area of the surface was 0.280 nm, 0.238 nm, and 0.592 nm, respectively, all of which were 1 nm or less, indicating sufficient flatness. On the other hand, when the Al composition ratio in the first Group III nitride semiconductor film was 30% (Experimental Example 7), the root mean square (RMS) roughness over a 30-μm square area of the surface was 17.4 nm, exceeding 1 nm, indicating a rough surface.I k

According to the Group III nitride semiconductor epitaxial wafer according to the present disclosure, by disposing as an intermediate layer a first Group III nitride semiconductor film containing Al and Ga as Group III elements, it is possible to ensure the flatness of the second Group III nitride semiconductor film at the uppermost surface.

### REFERENCE SIGNS LIST

2 Group III nitride semiconductor substrate

4 first Group III nitride semiconductor film

6 second Group III nitride semiconductor film

10 Group III nitride semiconductor epitaxial wafer

100 source chamber

101 source reaction chamber

102 first carrier gas supply port

103 reactive gas supply pipe

104 source boat

105 starting Group III element source

106 first heater

107 Group III element oxide gas discharge port

108 gas discharge port

109 connecting pipe

110 third heater

111 growth chamber

112 third carrier gas supply port

113 nitrogen element-containing gas supply port

114 second carrier gas supply port

115 second heater

116 seed substrate

117 substrate susceptor

118 gas supply port

119 exhaust port

What is claimed is:

1. A Group III nitride semiconductor epitaxial wafer comprising:
a Group III nitride semiconductor substrate exhibiting n-type conductivity and having a carrier concentration of 10²⁰cm⁻³ or more;
a first Group III nitride semiconductor film epitaxially grown on the Group III nitride semiconductor substrate, the first Group III nitride semiconductor film containing Al and Ga as Group III elements; and
a second Group III nitride semiconductor film epitaxially grown on the first Group III nitride semiconductor film.

2. The Group III nitride semiconductor epitaxial wafer according to claim 1, wherein the second Group III nitride semiconductor film at the uppermost surface has a root mean square (RMS) roughness value of 1 nm or less over a 30 μm square area of the surface.

3. The group III nitride semiconductor epitaxial wafer according to claim 1, wherein the Group III nitride semiconductor substrate is a gallium nitride substrate.

4. The Group III nitride semiconductor epitaxial wafer according to claim 1, wherein the second Group III nitride semiconductor film formed above the first Group III nitride semiconductor film includes a Group III nitride semiconductor film having an Al composition ratio lower than the Al composition ratio of the first Group III nitride semiconductor film.

5. The Group III nitride semiconductor epitaxial wafer according to claim 1, wherein the second Group III nitride semiconductor film formed above the first Group III nitride semiconductor film includes a Group III nitride semiconductor film having a carrier concentration of 10¹⁷ cm⁻³ or less.

6. The Group III nitride semiconductor epitaxial wafer according to claim 1, wherein the dopant element of the Group III nitride semiconductor substrate is oxygen.

7. The Group III nitride semiconductor epitaxial wafer according to claim 1, wherein the Al composition ratio relative to the total amount of the Group III elements of the first Group III nitride semiconductor film is 0.001 or more and 0.3 or less, where the total amount of the Group III elements in the first Group III nitride semiconductor film is 1.

8. The Group III nitride semiconductor epitaxial wafer according to claim 1, wherein the thickness of the first Group III nitride semiconductor film is 0.02 μm or more and 1 μm or less.

9. An electronic device using the Group III nitride semiconductor epitaxial wafer according to claim 1.

10. A method for producing a Group III nitride semiconductor epitaxial wafer, comprising:
forming a Group III nitride semiconductor substrate exhibiting n-type conductivity and having a carrier concentration of 10²⁰cm⁻³ or more by OVPE method;
epitaxially growing a first Group III nitride semiconductor film containing Al and Ga as Group III elements on the Group III nitride semiconductor substrate; and
epitaxially growing a second Group III nitride semiconductor film on the first Group III nitride semiconductor film.
